(19) United States
(12) Patent Application Publication
(10) Pub. No.: US 2020/0258823 A1
(43) Pub. Date: Aug. 13, 2020

(54) POWER SEMICONDUCTOR DEVICE AND MANUFACTURING METHOD OF THE SAME

(71) Applicant: HITACHI AUTOMOTIVE SYSTEMS, LTD., Hitachinaka-shi, Ibaraki (JP)

(72) Inventors: Takashi KUBOKI, Hitachinaka-shi (JP); Keiji KAWAHARA, Hitachinaka-shi (JP); Takeshi KONNO, Hitachinaka-shi (JP)

(73) Assignee: HITACHI AUTOMOTIVE SYSTEMS, LTD., Hitachinaka-shi, Ibaraki (JP)

(21) Appl. No.: 16/643,065

(22) PCT Filed: Jul. 9, 2018
(86) PCT No.: PCT/JP2018/025813

§ 371 Date: Feb. 28, 2020

(30) Foreign Application Priority Data
Aug. 30, 2017 (JP) 2017-164994

(51) Int. Cl. H01L 23/495; H01L 23/31; H01L 21/48; H01L 21/56

(52) U.S. Cl. CPC H01L 23/49568; H01L 23/3114; H01L 23/49513; H01L 21/565; H01L 23/49562; H01L 23/49575; H01L 21/4825; H01L 23/49524

(57) ABSTRACT

An object of the invention is to improve productivity while suppressing a reduction in a heat radiating performance of a power semiconductor device.

According to the invention, there is provided a manufacturing method of a power semiconductor device which includes a conductive member having a first surface and a second surface provided on a side opposite to the first surface and a power semiconductor element which is connected to the conductive member through a bonding material. The method includes a first procedure in which part of the first surface is pressed to form a concave portion leaving a portion flush with the first surface, and the conductive member is pressed to form a convex portion in the second surface, a second procedure in which the power semiconductor device is disposed in a top of the convex portion to face the concave portion of the first surface and a portion where the concave portion not formed, and the convex portion and the power semiconductor element are connected through the bonding material, and a third procedure in which at least the concave portion is filled with a sealing material.

### TECHNICAL FIELD

The invention relates to a power semiconductor device and a manufacturing method thereof, and particularly to a power semiconductor device related to a hybrid vehicle or an electric vehicle and a manufacturing method thereof.

### BACKGROUND ART

In a power semiconductor device using a power semiconductor element, a tendency to increase power is advanced, and mass production in a short period is required. In particular, the power semiconductor device used in a hybrid vehicle or an electric vehicle is advanced in high power, a heat radiating performance higher than thermal radiation is required for the power loss. In addition, the power semiconductor device is made in modules, and mass production is required at a low cost.

The power semiconductor device of PTL 1 includes a conductive material (lead frame) provided with a convex portion formed of a pull-out material (different strip). The convex portion of the conductive material is connected to the power semiconductor element through a conductive bonding material.

### CITATION LIST

### Patent Literature

PTL 1: JP 2012-74648 A

### SUMMARY OF INVENTION

### Technical Problem

An object of the invention is to improve productivity while suppressing a reduction in a heat radiating performance.

### Solution to Problem

According to the invention, there is provided a manufacturing method of a power semiconductor device which includes a conductive member having a first surface and a second surface provided on a side opposite to the first surface and power semiconductor element which is connected to the conductive member through a bonding material. The method includes a first procedure in which part of the first surface is pressed to form a concave portion leaving a portion flush with the first surface, and the conductive member is pressed to form a convex portion in the second surface, a second procedure in which the power semiconductor device is disposed in a top of the convex portion to face the concave portion of the first surface and a portion where the concave portion is not formed, and the convex portion and the power semiconductor element are connected through the bonding material, and a third procedure in which at least the concave portion is filled with a sealing material.

### Advantageous Effects of Invention

According to the invention, it is possible to improve productivity while suppressing a reduction in a heat radiating performance.

### BRIEF DESCRIPTION OF DRAWINGS

FIG. 1 is an exploded perspective view of a power semiconductor device according to an embodiment.

FIG. 2 is an exploded perspective view of a circuit body 120 where a sealing resin 122A is removed.

FIG. 3 is a cross-sectional view of a third conductive portion 102 viewed from a direction of arrow of a plane which passes through AA of FIG. 2.

FIG. 4(a) is a diagram illustrating a front view (upper drawing) of the third conductive portion 102 before forming a convex portion 117, and a cross-sectional view (lower drawing) of the third conductive portion 102 viewed from a direction of arrow of a plane which passes through DD.

FIG. 4(b) is a cross-sectional view of a state where the third conductive portion 102 before formation is disposed in a press machine.

FIG. 4(c) is a cross-sectional view of a state where the third conductive portion 102 in a first press procedure is disposed in the press machine.

FIG. 4(d) is a cross-sectional view of the third conductive portion 102 immediately before a second press procedure.

FIG. 4(e) is a diagram illustrating a front view (upper drawing) of the third conductive portion 102 after the convex portion 117 is formed, and a cross-sectional view (lower drawing) of the third conductive portion 102 viewed from a direction of arrow of a plane which passes through FF.

FIG. 4(f) is a cross-sectional view illustrating a first stage of a forming procedure of a first intermediate conductive portion 110 illustrated in FIG. 4(e).

FIG. 4(g) is a cross-sectional view illustrating a second stage of a forming procedure of the first intermediate conductive portion 110 illustrated in FIG. 4(e).

FIG. 5(a) is a perspective view after the circuit body 150 is over-molded with the sealing resin 122A.

FIG. 5(b) is a perspective view of the circuit body 150 after part of the sealing resin 122A is ground.

FIG. 6 is a cross-sectional view viewed from a direction of arrow of a plane which passes through GG of FIG. 5(b) in the circuit body 150 where a cooling fin 201 and an insulating member 200 are connected.

FIG. 7 is a cross-sectional view of the circuit body 150 viewed from a direction of arrow of a plane which passes through BB of FIG. 2.

FIG. 8 is a cross-sectional picture of the vicinity of a first concave portion 120 and a second concave portion 121 of FIG. 4(c).

### DESCRIPTION OF EMBODIMENTS

Hereinafter, embodiments of a power conversion device according to the invention will be described with reference to the drawings. Further, the same element in the drawings will be attached with the same symbol, and the redundant description will be omitted. The invention is not limited to the following embodiments, and various modifications and applications may be included in the scope of the technical ideas of the invention.

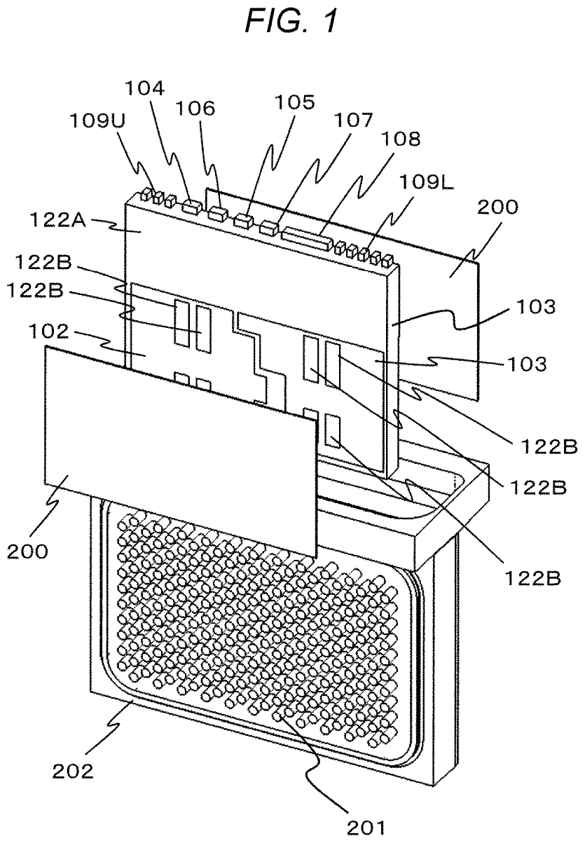

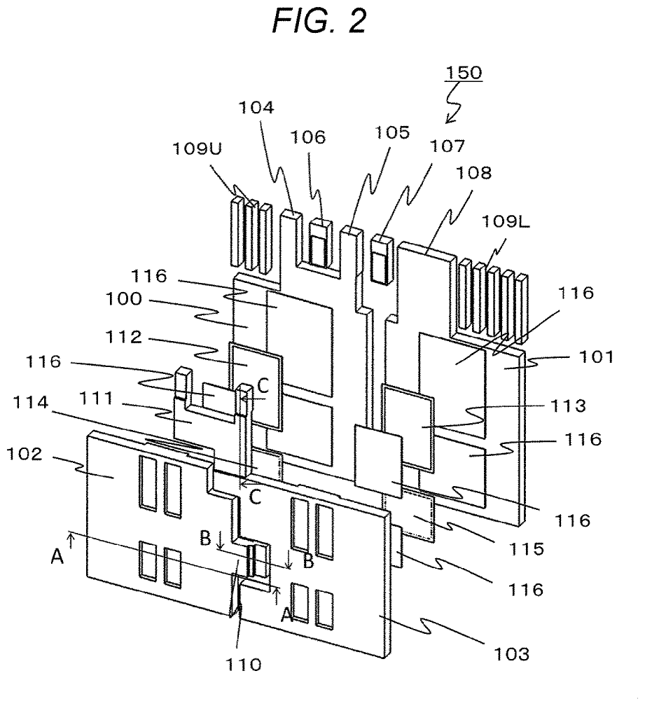

FIG. 1 is an exploded perspective view of a power semiconductor device according to an embodiment. FIG. 2 is an exploded perspective view of a circuit body 120 where a sealing resin 122A is removed.

The power semiconductor device is configured by the circuit body 150, an insulating member 200 interposing the circuit body 150, and a module case 202 which stores the insulating member 200 interposing the circuit body 150.

A third conductive portion 102 is sealed by the sealing resin 122A. The surface of part of the third conductive portion 102 which is opposite to the surface where a power semiconductor element and a diode are connected is exposed.

A fourth conductive portion 103 is sealed by the sealing resin 122A. The surface of part of the fourth conductive portion 103 which is opposite to the surface where the power semiconductor element and the diode are connected is exposed.

In addition, the sealing resin 122A seals parts of a first positive terminal 104, a second positive terminal 105, a first negative terminal 106, a second, negative terminal 107, an AC terminal 108, an upper arm signal connection terminal 109U, and a lower arm signal connection terminal 109L.

A sealing resin 122B seals concave portions of the third conductive portion 102 and the fourth conductive portion 103 illustrated in FIG. 2. An exposed surface of the sealing resin 122B becomes flush with the surfaces of the exposed third conductive portion 102 and the exposed fourth conductive portion 103.

The insulating member 200 is disposed to cover a first conductive portion 100, a second conductive portion 101, the third conductive portion 102, and the conductive portion 103 which are exposed. In addition, the insulating member 200 abuts on the inner wall of the module case 202, and is interposed between the module case 202 and the circuit body 150.

The module case 202 is a cooling vessel disposed in a refrigerant, and is provided with a cooling fin 201. The cooling fin 201 is formed in a matrix-like arrangement. The module case 202 has a role of efficiently transferring heat generated in the power semiconductor element, and thus is made of a material such as copper and aluminum of which the thermal conductivity is large and the electric resistance is small.

As illustrated in FIG. 2, the first conductive portion 100 is configured such that a collector electrode of the first power semiconductor element 112 and a cathode electrode of a first diode 114 are bonded through a conductive bonding material 116.

The second conductive portion 101 is configured such that a collector electrode of a second power semiconductor element 113 and a cathode electrode of a second diode 115 are bonded through the conductive bonding material 116.

The third conductive portion 102 is configured such that an emitter electrode of the first power semiconductor element 112 and an anode electrode of the second diode 114 are bonded through the conductive bonding material 116.

The fourth conductive portion 103 is configured such that an emitter electrode of the second power semiconductor element 113 and an anode electrode of the second diode 115 are bonded by the conductive bonding material 116.

The first positive terminal 104 and the second positive terminal 105 are connected to the first conductive portion 100. The first negative terminal 106 is connected to the fourth conductive portion 103 through a relay conductive portion 111. The second negative terminal 107 is connected to the fourth conductive portion 103 through the relay conductive portion 111.

The AC terminal 108 is provided at a position near the second power semiconductor element 113, and is connected to the second conductive portion 101. The AC terminal 108 is a terminal of a center portion (intermediate electrode) of an inverter circuit.

The upper arm signal connection terminal 109U is connected to a signal electrode of the first power semiconductor element 112 through a wire (not illustrated) made of aluminum (Al) or gold (Au). The lower arm signal connection terminal 109L is connected to a signal electrode of the second power semiconductor element 113 through a wire (not illustrated) made of aluminum (Al) or gold (Au).

A first intermediate conductive portion 110 is extended from the third conductive portion 102, and is connected to the second conductive portion 101 through the conductive bonding material 116.

The relay conductive portion 111 is extended from the fourth conductive portion 103, and is connected to the first negative terminal 106 and the second negative terminal 107 through the conductive bonding material 116.

The first power semiconductor element 112 is a semiconductor element which includes a collector electrode in one surface and an emitter electrode and a gate electrode on the other surface. The second power semiconductor element 113 is a semiconductor element which includes a collector electrode in one surface and an emitter electrode and a gate electrode on the other surface.

The first diode 114 has the anode electrode connected to the first conductive portion 100, and is disposed at a position away from a positive terminal and a negative terminal. The first diode 114 is electrically connected to the first power semiconductor element 112 in parallel.

The second diode 115 has the cathode electrode connected to the second conductive portion 101, and is disposed at a position away from a positive terminal and a negative terminal. The second diode 115 is electrically connected to the second power semiconductor element 113 in parallel.

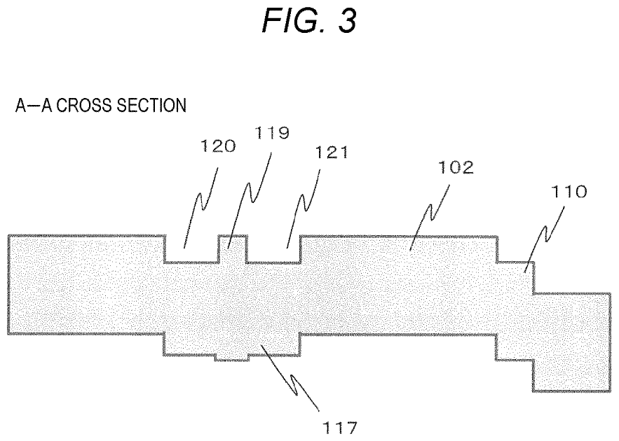

FIG. 3 is a cross-sectional view of the third conductive portion 102 viewed from a direction of arrow of a plane which passes through AA of FIG. 2.

A convex portion 117 is connected to the first power semiconductor element 112 and the first diode 114 through the conductive bonding material 116. The convex portion 117 is molded by pressing part of the third conductive portion 102.

A first concave portion 120 and a second concave portion 121 are molded by pressing part of the third conductive portion 102. At this time, the first concave portion 120 and the second concave portion 121 are provided such that a protruding portion 119 protruding from a bottom of the concave portion is left. The protruding portion 119 has a role of efficiently dissipating heat generated in the first power semiconductor element 112 and the first diode 114 to the cooling fin 201.

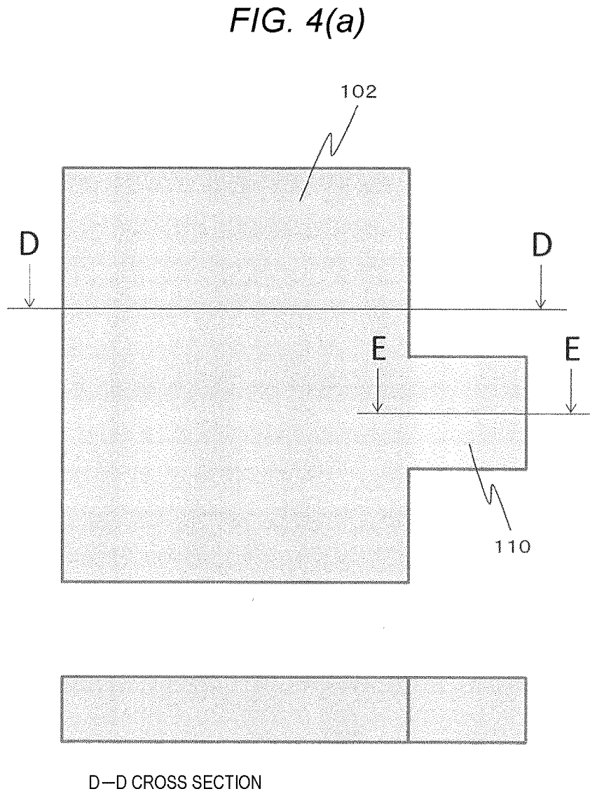

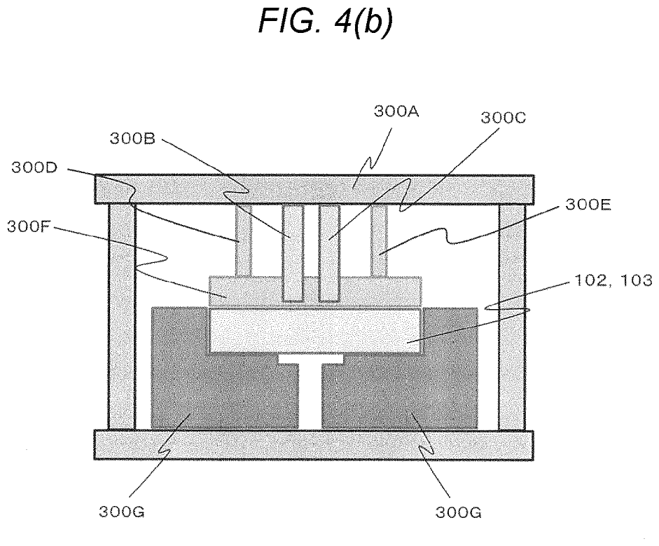

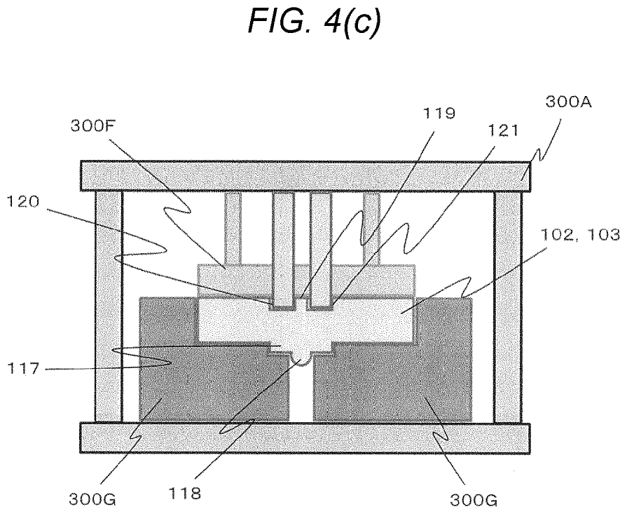

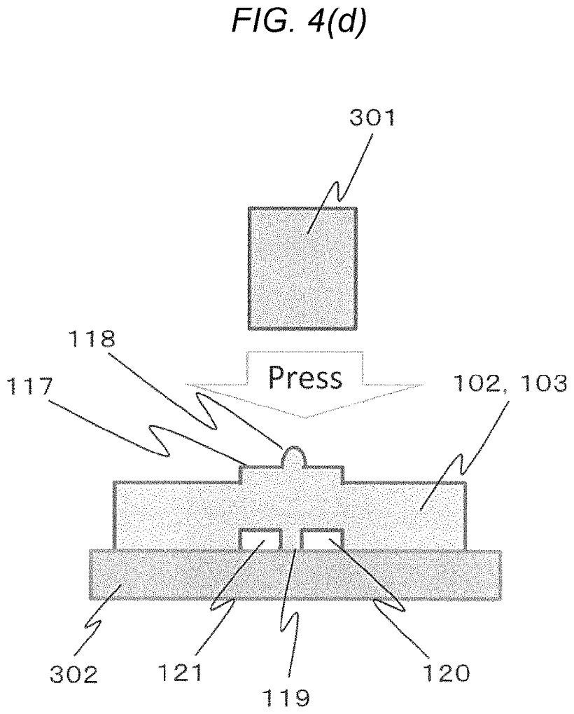

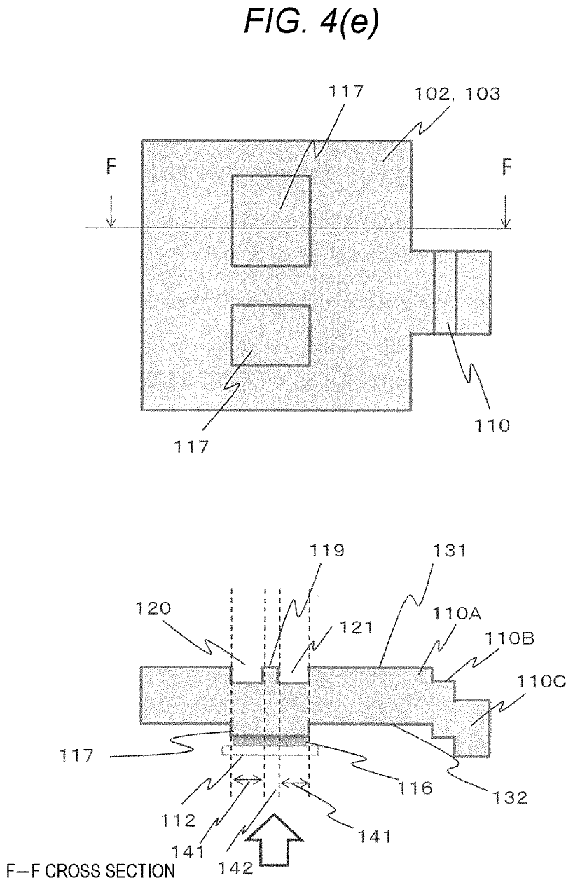

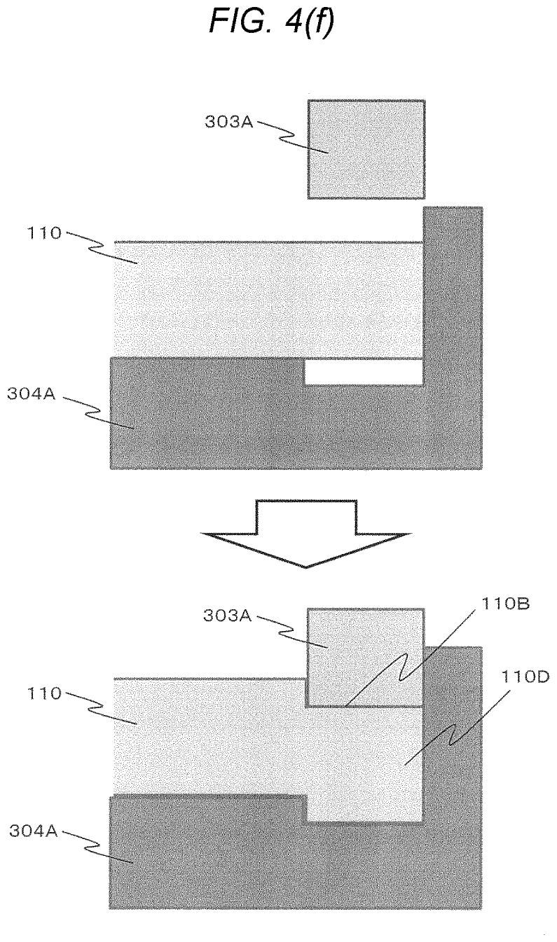

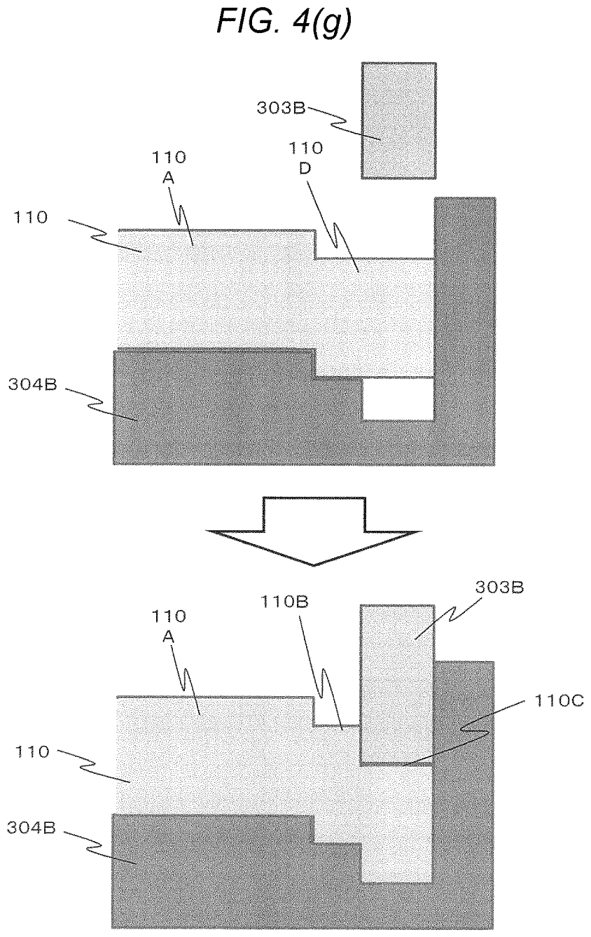

FIG. 4(a) is a diagram illustrating a front view (upper drawing) of the third conductive portion 102 before forming the convex portion 117, and a cross-sectional view (lower drawing) of the third conductive portion 102 viewed from a direction of arrow of a plane which passes through DD. The third conductive portion 102 before molding is configured in one plate, and the first intermediate conductive portion 110 is provided integrally. FIG. 4(b) is a cross-sectional view of a state where the third conductive portion 102 before formation is disposed in a press machine.

A first press jig 300A abuts on the upper surfaces of a first press portion 300B, a second press portion 300C, a third press portion 300D, and a fourth press portion 300E which serve as a press portion.

A first fixing jig 300F forms a through hole through which the first press portion 300B and the second press portion 300C pass, abuts on the lower surfaces of the third press portion 300D and the fourth press portion 300E, and abuts on the upper surface of the third conductive portion 102. With this configuration, the upper surface such as the third conductive portion 102 on the pressed surface side does not drift.

A second fixing jig 300G fixes the side surface such as the third conductive portion 102, and fixes the surface where the convex portion 117 is not formed. The second fixing jig 300G serves as a receiving jig in which the third conductive portion 102 or the like drifts to mold the convex portion 117.

FIG. 4(c) is a cross-sectional view of a state where the third conductive portion 102 in a first press procedure is disposed in the press machine.

A bump portion 118 is formed to face the protruding portion 119. The bump portion 118 is likely to cause a cavity in the top of the convex portion 117 when drifting plastically. If a cavity is generated in the top of the convex portion 117, the conductive bonding material or the sealing resin enters the cavity, and a heat radiating performance is lowered.

Therefore, the bump portion 118 is generated to suppress the deficiency of plastic drifting, so that the reduction in the heat radiating performance can be suppressed.

FIG. 4(d) is a cross-sectional view of the third conductive portion 102 immediately before a second press procedure.

A fifth press portion 301 molds the top of the convex portion 117 by pressing the bump portion 118. A third fixing jig 302 is a reception surface of pressing of the fifth press portion 301, and abuts on the protruding portion 119 and the surface such as the third conductive portion 102 on the opposite side to the surface where a semiconductor element and a diode are mounted.

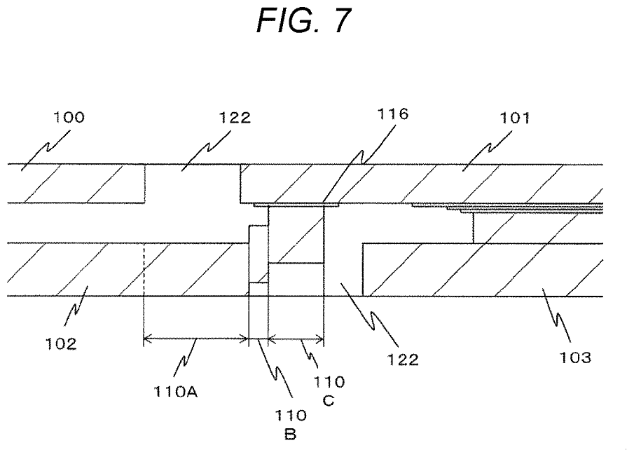

FIG. 4(e) is a diagram illustrating a front view (upper drawing) of the third conductive portion 102 after the convex portion 117 is formed, and a cross-sectional view (lower drawing) of the third conductive portion 102 viewed from a direction of arrow of a plane which passes through FF. FIG. 7 is cross-sectional view of the circuit body 150 viewed from a direction of arrow of a plane which passes through BB of FIG. 2.

The third conductive portion 102 includes a first region 141 which protrudes from a second surface 132 and is concave from a first surface 131, a bottom of the first concave portion 120 of the first region 141, and a second region 142 which protrudes from a bottom of the second concave portion 121.

When viewed in a direction perpendicular to the electrode surface of the power semiconductor element 112, the power semiconductor element 112 is overlapped on both the first region 141 and the second region 142.

Further, the power semiconductor element 112 is connected to the first region 141 and the second region 142 through the conductive bonding material 116 such as a solder material.

In the first intermediate conductive portion 110, a first region 110A, a second region 110B, and a third region 110C are provided. The first region 110A is formed to become flush with a heat dissipation surface of the third conductive portion 102, and serves as a heat dissipation surface. With this configuration, the area of the heat dissipation surface can be expanded, and the heat radiating performance is improved.

In addition, the third region 110C is formed to have the area where a peripheral fillet can be formed to stabilize the connectivity of the conductive bonding material 116 when being connected to the second conductive portion 101.

The area of the second region 110B is smaller than that of each of the first region 110A and the third region 110C. For example, accuracy and strength after the pressing are lowered by pressing about half the plate thickness or more. In addition, a cross section where the current flows becomes small, and the inductance of the main circuit is also increased.

Then, in order to suppress the reduction in accuracy after the pressing and to suppress the increase in inductance of the main circuit, the pressing is performed in multiple steps to form the first region 110A, the second region 110B, and the third region 110C so as to mold the first intermediate conductive portion 110.

As illustrated in FIG. 7, the first intermediate conductive portion 110 of the third conductive portion 102 is connected to the second conductive portion 101 through the conductive bonding material 116. A second intermediate conductive portion 111 is also configured to provide the first region, the second region, and the third region similarly to the first intermediate conductive portion 110.

FIG. 4(f) is a cross-sectional view illustrating a first stage of a forming procedure of the first intermediate conductive portion 110 illustrated in FIG. 4(e).

A sixth press portion 303A is a press portion to mold the second region 110B of the first intermediate conductive portion 110. A first mold jig 304A is a receiving jig for molding the second region 110B. Through the procedure of the first stage, an intermediate member 110D of the first intermediate conductive portion 110 is formed.

FIG. 4(f) is a cross-sectional view illustrating a second stage of the forming procedure of the first intermediate conductive portion 110 illustrated in FIG. 4(e).

A seventh press portion 303B is a press portion for molding the third region 110C of the first intermediate conductive portion 110. A second mold jig 304B is a receiving jig for molding the third region 110C.

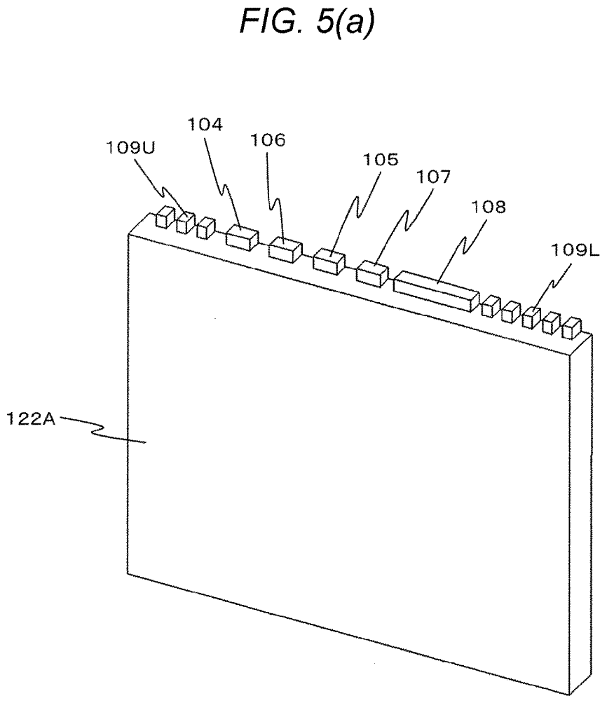

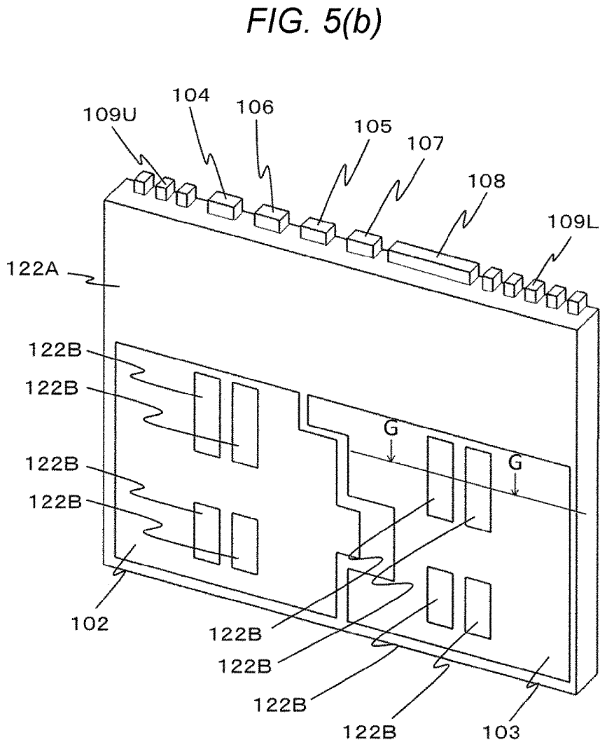

FIG. 5(a) is a perspective view of the circuit body 150 after the sealing resin 122A is over-molded.

The sealing resin 122A over-molds and seals the third conductive portion 102 and the fourth conductive portion 103 illustrated in FIG. 2. In other words, the first concave portion 120 and the second concave portion 121 are filled with the sealing resin 122A illustrated in FIG. 4(c).

In addition, the sealing resin 122A seals parts of the first positive terminal 104, the second positive terminal 105, the second negative terminal 106, the second negative terminal 107, the AC terminal 108, the upper arm signal connection terminal 109U, and the lower arm signal connection terminal 109L.

FIG. 5(b) is a perspective view of the circuit body 150 after part of the sealing resin 122A is ground.

Each part of the sealing resin 122A, the third conductive portion 102, and the fourth conductive portion 103 is ground. With this configuration, the third conductive portion 102, the fourth conductive portion 103, and the sealing resin 122B are exposed. In addition, the sealing resin 122B seals the concave portions of the third conductive portion 102 and the fourth conductive portion 103, and becomes flush with the surfaces of the exposed third conductive portion 102 and the exposed conductive portion 103.

The insulating member 200 illustrated in FIG. 1 is disposed to cover a first conductive portion 100, a second conductive portion 101, the third conductive portion 102, and the fourth conductive portion 103 which are exposed.

The first concave portion 120 and the second concave portion 121 are connected to the insulating member 200 through the sealing resin 122B.

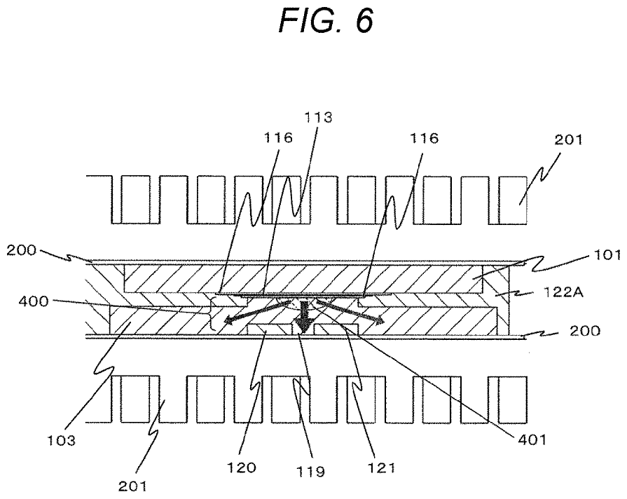

FIG. 6 is a cross-sectional view viewed from a direction of arrow of a plane which passes through GG of FIG. 5(b) in the circuit body 150 where the cooling fin 201 and the insulating member 200 are connected.

A heat radiating direction 400 indicates a flow of heat radiation of the heated power semiconductor element 113 or the like.

A high-density place 401 is formed by pressing the bump portion 118 as illustrated in FIG. 4(d), and has a density higher than the other portion of the fourth conductive portion 103. The high-density place 401 has a thermal resistance smaller than the other portion of the fourth conductive portion 103.

The high-density place 401 is formed at a position facing the protruding portion 119. With this configuration, a large amount of the heat of the heated power semiconductor element 113 or the like flows to the facing protruding portion 119 such as in the heat radiating direction 400.

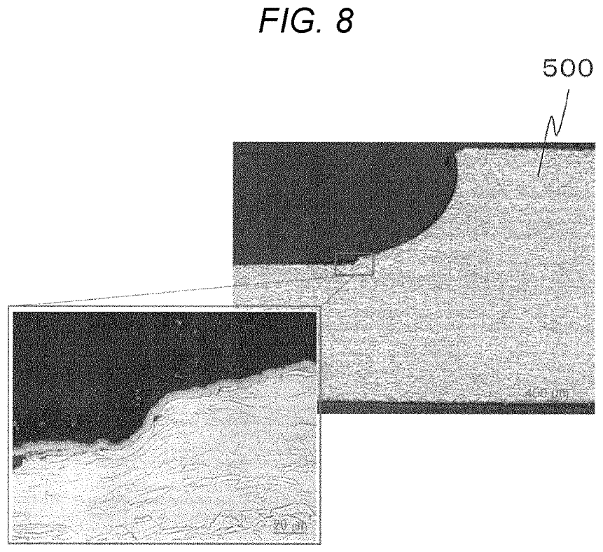

FIG. 8 is a cross-sectional picture of the vicinity of the first concave portion 120 and the second concave portion 121 of FIG. 4(c).

In a case where the third conductive portion 102 is formed by the press procedure according to this embodiment illustrated in FIG. 4(c), it is possible to check a plastic flowability 500 in the ends of the bottom of the first concave portion 120 and the second concave portion 121 where a large press load is applied.

### REFERENCE SIGNS LIST

100 first conductive portion
101 second conductive portion
102 third conductive portion
103 fourth conductive portion
104 first positive terminal
105 second positive terminal
106 first negative terminal
107 second negative terminal
108 AC terminal
109U upper arm signal connection terminal
109L lower arm signal connection terminal
110 first intermediate conductive portion
110A first region
110B second region
110C third region
110D intermediate member
111 relay conductive portion
112 first power semiconductor element
113 second power semiconductor element
114 first diode
115 second diode
116 conductive bonding material
117 convex portion
118 bump portion
119 protruding portion
120 first concave portion
121 second concave portion
122B resin sealing
131 first surface
132 second surface
141 first region
142 second region
150 circuit body
200 insulating member
201 cooling fin
202 module case
300A first press jig
300B first press portion
300C second press portion
300D third press portion
300E fourth press portion
300F first fixing jig
300G second fixing jig
301 fifth press portion
302 third fixing jig
303A sixth press portion
303B seventh press portion
304A first mold jig
304B second mold jig
400 heat radiating direction
401 high-density place
500 plastic flowability

1. A manufacturing method of a power semiconductor device which includes a conductive member having a first surface and a second surface provided on an opposite side to the first surface and a power semiconductor element which is connected to the conductive member through a bonding material, the method comprising:
a first procedure in which part of the first surface is pressed to form a concave portion leaving a portion flush with the first surface, and the conductive member is pressed to form a convex portion in the second surface;
a second procedure in which the power semiconductor device is disposed in a top of the convex portion to face the concave portion of the first surface and a portion where the concave portion is not formed, and the convex portion and the power semiconductor element are connected through the bonding material; and
a third procedure in which at least the concave portion is filled with a sealing material.

2. The manufacturing method of the power semiconductor device according to claim 1,
wherein the first procedure includes a procedure of lowering a height of a protruding portion formed in the top of the convex portion after the conductive member plastically flows.

3. The manufacturing method of the power semiconductor device according to claim 2,
wherein the height of the protruding portion formed in the top of the convex portion is lowered by a press procedure.

4. The manufacturing method of the power semiconductor device according to claim 1,
wherein, in the third procedure, the first surface of the conductive member is covered with the sealing material, and the sealing material is removed to leave the sealing material in the concave portion.

5. The manufacturing method of the power semiconductor device according to claim 2,
wherein, in the first procedure,
the concave portion on a side near the first surface includes a first concave portion and a second concave portion, and the protruding portion is formed to face a space between the first concave portion and the second concave portion.

6. The manufacturing method of the power semiconductor device according to claim 1,
wherein the first procedure includes a procedure of forming a terminal extending from an edge of the conductive member by pressing.

7. The manufacturing method of the power semiconductor device according to claim 6,
wherein the conductive member includes a first conductive member and a third conductive member which interpose a power semiconductor element which form an upper arm circuit of an inverter circuit, and a second conductive member and a fourth conductive member which interpose a power semiconductor element which form a lower arm circuit of the inverter circuit,
wherein the third conductive member forms the terminal, and
wherein the terminal faces part of the second conductive member, and is connected to the second conductive member.

8. The manufacturing method of the power semiconductor device according to claim 7,
wherein the terminal forms a non-press surface which becomes flush with the second surface, and a press surface which has a height different from the non-press surface and is formed by pressing, and
wherein the non-press surface is larger than the press surface.

9. The manufacturing method of the power semiconductor device according to claim 6,
wherein the terminal forms a main terminal which transfers a current flowing to the power semiconductor element.

10. A power semiconductor device, comprising:
a power semiconductor element;
a conductive portion which includes a first surface and a second surface provided on an opposite side to the first surface;
a solder material which connects the power semiconductor element and the conductive portion; and
a sealing material which seals the conductive portion,
wherein the conductive portion includes a first region which protrudes from the second surface and is concave from the first surface, and a second region which protrudes from the concave bottom of the first region,
wherein, when viewed from a direction perpendicular to an electrode surface of the power semiconductor element, the power semiconductor element is overlapped with both of the first region and the second region,
wherein the power semiconductor element is connected to the first region and the second region through the solder, and
wherein the concave portion of the first region is filled with part of the sealing material.
